(19) United States
(12) Patent Application Publication
(10) Pub. No.: US 2026/0128593 A1
(43) Pub. Date: May 7, 2026

(54) CONSTRUCTION EQUIPMENT WITH ADVANCED POWER MANAGEMENT FUNCTIONS

(71) Applicant: HUSQVARNA AB, Huskvarna (SE)

(72) Inventor: Tommy OLSSON, Lerum (SE)

(21) Appl. No.: 19/115,412

(22) PCT Filed: Sep. 28, 2023
(86) PCT No.: PCT/EP2023/076947

§ 371 Date: Mar. 26, 2025

(30) Foreign Application Priority Data
Sep. 29, 2022 (SE) 2251119-0

(51) Int. Cl. H02J 3/32; B60L 1/00; B60L 53/18; B60L 58/12; E02F 9/20; G01R 19/00; H02H 9/02; H02J 3/46

(52) U.S. Cl. CPC H02J 3/322; B60L 1/003; B60L 53/18; B60L 58/12; G01R 19/003; H02H 9/02; H02J 3/46; B60L 2200/40; E02F 9/2091

(57) ABSTRACT

A control unit (110) for controlling power consumption by construction equipment (100) powered at least partly via an electrical mains cable connection (160), where the control unit (110) is arranged to obtain data indicative of a current drawn by the construction equipment (100) as function of time, where the control unit (110) is arranged to process the obtained data using at least a first and a second averaging function, where the first averaging function is associated with a shorter averaging time window compared to the second function, where the outputs of the at least two functions are associated with respective function acceptance criteria, where the control unit (110) is arranged to limit the current drawn by the construction equipment (100) in case any of the function outputs does not meet the respective function acceptance criterion.

### TECHNICAL FIELD

The present disclosure relates to construction equipment, such as electrically powered demolition robots, floor grinders, power trowels, core drilling equipment, cut-off tools, blasters, scrapers, and wall saws. There are disclosed methods and control units for controlling power consumption by the construction equipment.

### BACKGROUND

Demolition robots are relatively light-weight and agile construction machines which can be used for various tasks, such as smaller excavation jobs, transportation, and of course demolition tasks.

Demolition robots are often electrically powered via cable from electrical mains. The machines may draw considerable power during operation, and therefore require large fuses, e.g., with rated currents on the order of 32 A, in order to support full functionality. However, many work sites only offer 16 A rated connections to electrical mains. In order to be able to work under these conditions, there is a need to limit the power drawn by the machines.

EP2842213 B1 discusses hybrid power systems which uses a battery to complement an electrical mains connection with insufficient rated current.

EP2589709 A2 describes a demolition robot which can be configured in an operation mode where power consumption is limited. The power limitation is achieved by adjusting control curves of the valves comprised in the hydraulic system of the machine.

Other types of power-hungry construction equipment include floor grinders, power trowels, core drilling equipment, cut-off tools, blasters, scrapers, and wall saws. These machines may in some cases be associated with the same power issue.

Despite the development work done to-date, there is a need for further improvements in power control of demolition robots and other types of construction equipment.

### SUMMARY

It is an object of the present disclosure to provide improved techniques for managing the power consumption of construction equipment such as demolition robots, floor grinders, power trowels, core drilling equipment, cut-off tools, blasters, scrapers, and wall saws. This object is at least in part obtained by a control unit for controlling power consumption by construction equipment that is powered at least partly via an electrical mains cable connection. The control unit is arranged to obtain data indicative of a current drawn by the construction equipment as function of time. The control unit is also arranged to process the obtained data using at least a first and a second averaging function, where the first averaging function is associated with a shorter averaging time window, i.e., a larger filtering bandwidth, compared to the second function and where the outputs of the at least two functions are associated with respective and different function acceptance criteria, such as acceptance thresholds. The control unit is furthermore arranged to trigger an automated power consumption related action by the construction equipment in case any of the function outputs does not meet the respective function acceptance criterion. This automated power consumption related action may comprise, e.g., automatically limiting the current drawn by the construction equipment to reduce the risk of tripping a fuse and/or triggering an automated notification to a user to inform the user of the risk of tripping a fuse such that the user can take action to reduce the power consumption of the equipment. By the disclosed techniques, a machine such as a demolition robot or some form of concrete processing equipment may be allowed to temporarily exceed a rated current of a fuse, as long as the long-term current consumption (as indicated by the second averaging function output) over the monitored time period satisfies the long term acceptance criteria. This added freedom in transient power consumption improves performance of the construction equipment, in particular at construction sites with low-rated fuses. As noted above, the system can either be configured to automatically limit the current drawn by the construction equipment, or just trigger an automated notification to a user. Some systems can be configured to first trigger generation of a warning, and then trigger limitation of the drawn current after some time in case the operator does not act to reduce power consumption in response to the notification. The notification can thus serve as a warning, or a heads-up, informing the operator that current consumption is high and that there is a risk of tripping the electrical mains fuse, but leaves the decision whether to actually reduce power consumption or risk blowing the fuse to the operator.

According to some aspects, the control unit comprises a current sensor arranged to measure a current drawn via the electrical mains cable connection. The data indicative of the current drawn by the construction equipment is then obtained at least in part from the current sensor. This is a reliable way to measure actual current consumption by a machine.

According to some other aspects, the control unit is arranged to estimate the current drawn by the construction equipment based on a generated hydraulic pressure and flow in a hydraulic system of the construction equipment and/or based on an operation by an electric machine or electric actuator of the construction equipment. The data indicative of the current drawn by the construction equipment then comprises the estimated current, in addition to or without measured current data. This option may be applicable with advantage in cases where there is no current sensor installed, or in cases where the current sensor is inoperable for some reason, or where there is a need to complement the data from the current sensor. The current drawn by the construction equipment can also be estimated before a control command is actually given, i.e., this technique can also be used to estimate a future current consumption, i.e., predict future current consumption, given information about an expected pressure and/or flow in the system, which can be obtained, e.g., from a hydraulic pump set-point or the like. The current consumption by an electric machine or electric actuator can also be predicted in this manner.

At least one of the first and the second averaging function can be a moving average filter in which case the acceptance criterion preferably comprises a threshold value against which the output of the averaging filter can be compared. At least one of the first and the second averaging functions normally has a low-pass filter characteristic, and the threshold value is preferably determined in dependence of a construction site fuse setting, e.g., as a factor multiplied by the nominal rated current of the fuse. The higher the fuse rating, the higher the threshold. The two or more averaging functions are normally associated with different thresholds, i.e., different acceptance criteria, configured in dependence of the fuse characteristics with which the equipment is intended to operate.

According to other aspects, at least one of the first and the second averaging function is realized by a machine learning (ML) algorithm or other structure based on artificial intelligence, such as a neural network, configured to determine if a respective acceptance criterion is fulfilled based on training data comprising power consumption patterns and power outages for different construction site fuse settings. This approach is a bit more flexible compared to using a moving average function or the like together with a threshold and will sometimes capture more complex patterns in power consumption likely to trip a fuse compared to the averaging functions. However, the approach also adds computational burden, which is a drawback.

The control unit may be arranged to limit the current drawn by the construction equipment by adjusting one or more hydraulic valve control curves. This method is effective and dependable, and provides a satisfactory decrease in current consumption in most cases. The control unit may also be arranged to limit the current drawn by the construction equipment by adjusting an operation parameter of a hydraulic pump comprised in a hydraulic system of the construction equipment such as to reduce a hydraulic system pressure of the construction equipment. In a similar manner, the control unit may also be arranged to limit the current drawn by the construction equipment by adjusting an operation of an electric machine and/or electric actuator of the construction equipment, e.g., by reducing a speed of operation, or an applied pressure associated with some tool of the equipment.

The control unit is preferably arranged to gradually limit the current drawn according to a pre-determined function in case any of the function outputs does not meet the respective function acceptance criterion. The gradual limitation provides a more graceful degradation in performance, which is an advantage. The control unit can also be arranged to gradually remove an imposed limitation on the current drawn according to a pre-determined function in case all of the function outputs meet their respective function acceptance criterion. This way abrupt changes in power consumption are avoided, which is an advantage.

According to other aspects, the control unit is arranged to store a recently drawn current in the event of an electrical mains power outage in a storage medium of the control unit. This way the system can perform a type of diagnostic operation of sorts, and see at which current the fuse was tripped. The control unit can also be arranged to store recent function outputs in the event of an electrical mains power outage in a storage medium of the control unit, and also to re-configure one or more of the acceptance criteria based on the stored recent function outputs in response to an electrical mains power outage. This is an advantage since the control system can be adapted to better fit the characteristics of the electrical mains at a given construction site.

The control units and systems discussed herein can also be used to manage a group of machines operating on the same electrical power source, i.e., drawing current via the same fuse or the same group of fuses on a construction site. Towards this end, the control unit can be arranged to obtain the data indicative of the current drawn by the construction equipment as an aggregated current drawn jointly by two or more pieces of equipment. In this case, groups of machines can be managed as a single consumer, and controlled accordingly, which is an advantage. The control unit can, for instance, be arranged to obtain data indicative of current consumption via wireless link from the two or more pieces of equipment. The control unit can also be arranged as a distributed control unit arranged to obtain data indicative of current consumption via wireless links inbetween the two or more pieces of equipment.

The control unit is optionally arranged to limit the current drawn by the two or more pieces of equipment according to a pre-determined priority order, which allows the system to prioritize some devices over others, which is an advantage. The control unit can also be arranged to limit the current drawn by the two or more pieces of equipment according to a pre-determined decrease distribution, such as a uniform distribution or a relative distribution. A random back-off pattern of decrease can also be applied, where machines back off their power consumption in a random manner.

Aspects of the present disclosure also relate to hybrid electrical power systems that comprise electrical energy storage (ESS) arrangements in combination with electrical mains connections. Thus, according to some aspects, the control unit is configured to control power consumption by construction equipment that is powered at least partly by an ESS in addition to the electrical mains cable connection. In this case the data obtained by the control unit is indicative of a current drawn by the construction equipment specifically over the electrical mains cable connection (and not from the ESS) as function of time. The automated power consumption related action in this case comprises control of electrical energy transferred to and/or from the ESS based on the averaging function outputs in relation to their respective filter acceptance criteria. Several advantages are obtained in this manner, such as a reduced ESS energy consumption and in many cases also a reduced wear on the ESS. The charging of the ESS from the electrical mains cable connection can also be optimized in this manner, as will be discussed in more detail below.

There are also disclosed herein methods and various forms of construction equipment associated with the same advantages as discussed above in connection to the control units.

Generally, all terms used in the claims are to be interpreted according to their ordinary meaning in the technical field, unless explicitly defined otherwise herein. All references to “a/an/the element, apparatus, component, means, step, etc.” are to be interpreted openly as referring to at least one instance of the element, apparatus, component, means, step, etc., unless explicitly stated otherwise. The steps of any method disclosed herein do not have to be performed in the exact order disclosed, unless explicitly stated. Further features of, and advantages with, the present invention will become apparent when studying the appended claims and the following description. The skilled person realizes that different features of the present invention may be combined to create embodiments other than those described in the following, without departing from the scope of the present invention.

### BRIEF DESCRIPTION OF THE DRAWINGS

The present disclosure will now be described in more detail with reference to the appended drawings, where:

FIG. 1 illustrates an example demolition robot;

FIG. 2 shows a remote control device for controlling a demolition robot;

FIG. 3 is a graph illustrating power consumption over time;

FIG. 4 illustrates example properties of some fuses;

FIG. 5 is a flow chart illustrating methods;

FIG. 6 schematically illustrates a control unit;

FIG. 7 schematically illustrates a computer program product;

FIG. 8 illustrates a group of machines connected to the same power source;

FIG. 9 schematically illustrates a hybrid electrical power system;

FIG. 10 shows an example hybrid electrical power system with a DC-bus; and

FIGS. 11A-B illustrate an example use case of power consumption control.

### DETAILED DESCRIPTION

Aspects of the present disclosure will now be described more fully with reference to the accompanying drawings. The different devices and methods disclosed herein can, however, be realized in many different forms and should not be construed as being limited to the aspects set forth herein. Like numbers in the drawings refer to like elements throughout.

The terminology used herein is for describing aspects of the disclosure only and is not intended to limit the invention. As used herein, the singular forms “a”, “an” and “the” are intended to include the plural forms as well, unless the context clearly indicates otherwise.

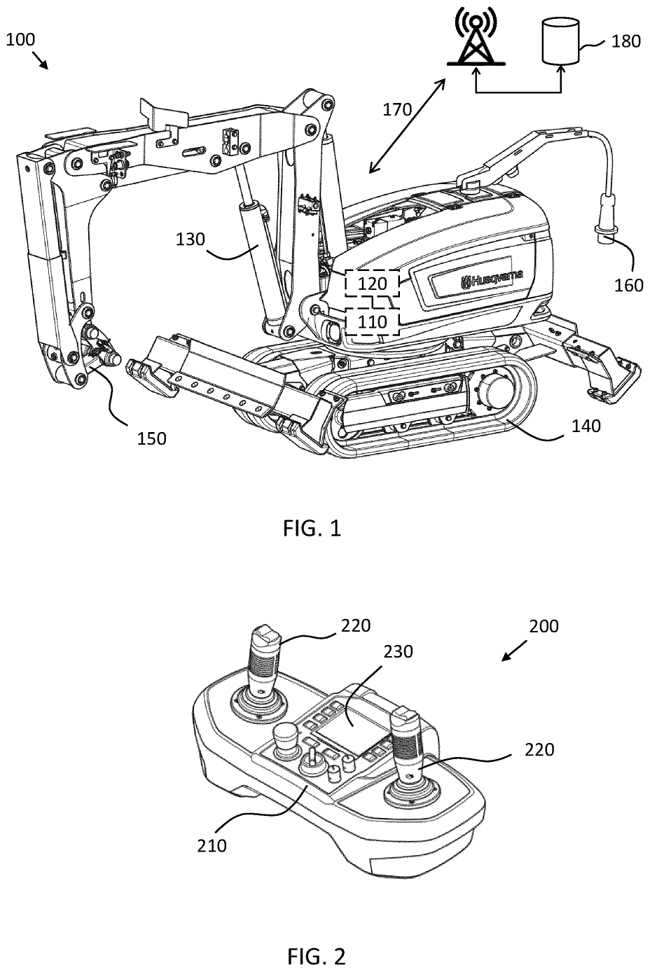

FIG. 1 illustrates example construction equipment 100, in this case a demolition robot. A demolition robot is a light-weight construction machine which can be used for various work tasks, such as smaller demolition tasks. The demolition robot 100 comprises a control unit 110 which controls the general operation of the robot, often including a hydraulic system 120 that powers the different actuators 130 on the robot, such as its tracks 140 and the tool carrier 150. The robot 100 is powered via a cable 160 arranged to connect the robot to electrical mains.

The present disclosure is also applicable to other forms of construction equipment, such as concrete floor grinders, core drilling equipment, cut-off tools (also known as concrete power cutters), power troweling machines, blasters, scrapers, and concrete wall saws (abrasive saws arranged to be fixed to a concrete work object to form a straight cut in the work object). The techniques discussed herein can, generally, be applied to any type of electrically or hybrid-electrically powered construction equipment, and also to groups of machines which collectively share the same electrical power source.

According to some aspects, the construction equipment comprises a hybrid electrical power system, where the electrical mains connection 160 is complemented by an ESS arrangement that can provide extra power to the equipment 100 when the electrical mains connection cannot provide the required power.

The demolition robot 100 is often remote controlled by a user located some distance away from the robot 100, e.g., using a remote control device 200 of the kind exemplified in FIG. 2. Some demolition robots also comprise more advanced connectivity systems that allow communication between the machine 100 and a remote server 180 over a wireless link 170. This allows remote software upgrade functions and also control of the machine from longer distances compared to when using the remote control 200. The wireless communication link may also be used to facilitate communication in-between different pieces of construction equipment. An example application of such communication will be discussed below in connection to FIG. 8.

The remote control 200 comprises a control unit 210 and control means 220. A display 230 provides information about the operation of the demolition robot 100 to a user. A user may configure various functions on the demolition robot 100 via the remote control 200, such as setting thresholds and the like.

A problem, as noted above, is that the fusing of an electrical mains connection at a work site may be smaller than the maximum current consumption of the demolition robot 100, i.e., the fuses may have a rated current IN below a maximum current consumption of the machine 100. In order to not trip a fuse on the incoming power to the machine 100, a setting can be made available, e.g., in the remote control 200 to limit the maximum current or power drawn by the machine 100 via the electrical mains connection 160.

It is known to impose a strict limitation on instantaneous current drawn by the machine 100. With a strict limitation on instantaneous current consumption the construction equipment 100 will not be allowed to consume more power than the configured power limitation threshold and may thus be used also at construction sites with smaller fuses than the rating of the construction equipment. However, this strict limitation significantly limits the operations that the construction equipment can perform at the work site, such as operating breakers and other more power consuming tools. Instead of imposing a strict limitation of, e.g., 16 A on the maximum current consumption of the machine 100, it is proposed herein to instead calculate average current consumptions over different time windows, and associate separate acceptance criteria with each such time window, in dependence of the current fuse configuration at a given work site. This allows for a higher power consumption by the construction equipment over a shorter time windows, as long as the power consumption over a larger time window meets certain acceptance criteria associated with the longer duration time window, thereby increasing the number of operations possible to perform with the equipment at sites with smaller fuses. For instance, a demolition robot will be allowed to use a high power consumption breaker at construction sites with small fuses, as long as the use is of limited time duration.

Miniature circuit breakers (MCB) are made according to different tripping characteristics, referred to as an MCB class. MCB classes B, C, D, K and Z will be discussed below in connection to FIG. 4. The techniques disclosed herein are, however, not limited to any particular MCB class of fuses.

According to an example of the herein proposed techniques, average current consumptions Ī_{T}_{_{w}} by the machine 100 are calculated over one or more time windows of different lengths. In other words a metric such as

$${\overline{I}}_{{T}_{w}} = \frac{1}{{T}_{w}} {\int }_{t = 0}^{t = {T}_{w}} i ( t ) dt$$

where i(t) is instantaneous current as function of time t, can be determined for some different time window durations T_{w}, such as 1, 5, 10, 20 and 60 minutes. It is noted that many different types of averages can be calculated, such as weighted averages. The present disclosure is not limited to any particular form of averaging operation or averaging function. Each average value metric will have a different acceptance criterion, such as a threshold value. For example:

$${\overline{I}}_{{T}_{w = 1 min}} < 1.5 {I}_{N}$$

$${\overline{I}}_{{T}_{w = 5 min}} < 1.4 {I}_{N}$$

$${\overline{I}}_{{T}_{w = 10 min}} < 1.3 {I}_{N}$$

$${\overline{I}}_{{T}_{w = 20 min}} < 1.2 {I}_{N}$$

$${\overline{I}}_{{T}_{w = 60 min}} < 1.1 {I}_{N}$$

where I_{N} is the rated current of the fuses at the construction work site. The different average values can then be updated for example every minute or computed as moving averages. If the average current is above the threshold value for some of the time windows, the maximum allowable power consumption by the machine 100 can, for instance, be lowered by 5% or by some other pre-determined value. The test can then be repeated regularly, and the power consumption will therefore go down gracefully without tripping the fuses on the work site. If all averages are below their respective thresholds, then the allowable current consumption by the machine 100 can be increased again, preferably according to a graceful function, such as by gradual relative increases. The averaging functions may also comprise elements of prediction, i.e., the output of the functions may be designed so as to represent an estimated future value of an averaging function output, such as an averaging filter output. This can be achieved by implementing, e.g., Kalman filter based on a constant current consumption model, or a constant change current consumption model. Kalman filters are generally known, as are Kalman filter predictors, and will therefore not be discussed in more detail herein.

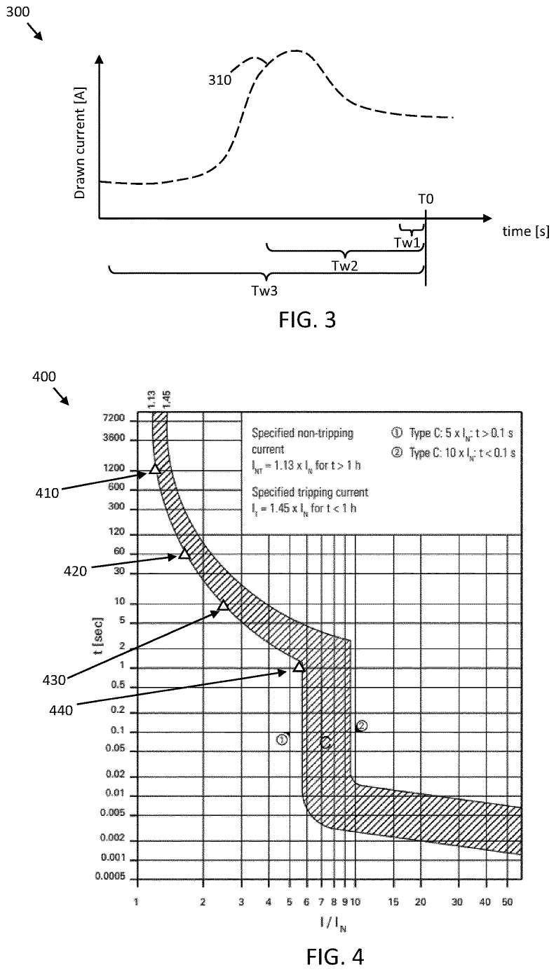

FIG. 3 is a graph illustrating current drawn by a demolition robot as function of time. The current consumption is relatively low at first, but then increases, before settling down at some intermediate level. Three time windows Tw1, Tw2 and Tw3 are illustrated. The control unit may compute an average drawn current over these three time windows, and the result of the averaging operation then constitutes the output of three averaging functions.

The acceptance criteria and the different averaging functions are preferably matched to the tripping characteristics of the MCB in use at the work site. For a class C MCB, with tripping characteristics 400 illustrated in FIG. 4, the time periods for averaging and the associated thresholds can be configured as illustrated by the triangles 410, 420, 430, 440 in FIG. 4, i.e., spread out along the lower border of the tripping characteristic curve. It is noted that the number of averaging functions used may vary, as well as their location on the x-axis and the y-axis of the tripping characteristic.

The acceptance criteria need not be associated with a specific type of fuse or the like but can be generally configured by the operator at the work site. The operator can, for instance simply configure a short term current limit and a long term current limit associated with two predetermined time intervals, or according to more advanced embodiments specify a number of time durations with associated average current or power limits. The operator can of course also download a configuration file to the control unit which comprises acceptance criteria to be used for a given work task and/or at a given work site. It may be advantageous to configure current limits in dependence of a nominal rated current I_{N}. An operator can, for instance, manually configure a number of time periods Tᵢ in seconds or minutes, where i=1, 2, . . . N with associated average current thresholds xᵢI_{N} defined as multiples of a nominal rated current I_{N}, as exemplified below for three configured time periods with associated acceptance criteria.

$${\overline{I}}_{{T}_{w = {T}_{1}}} < {x}_{1} {I}_{N}$$

$${\overline{I}}_{{T}_{w = {T}_{2}}} < {x}_{2} {I}_{N}$$

$${\overline{I}}_{{T}_{w = {T}_{3}}} < {x}_{3} {I}_{N}$$

The fuse tripping characteristics exemplified in FIG. 4 are generally known as a trip curve. The characteristics shown in FIG. 4 is a class C trip curve and is included herein for illustrative purposes only. The x-axis shows multiple of rated current I_{N} and the y-axis shows time in seconds. MCBs are generally available with class B, C, D, K and Z trip curve characteristics. An MCB with class B trip characteristics trips when the current flowing through it reaches between 3 to 5 times rated current. These MCBs are suitable for cable protection. MCBs with class C trip characteristics trips more or less instantaneously when the current flowing through it reaches between 5 to 10 times the rated current. MCBs with class C characteristics are commonly found in domestic and residential sites where they are used for electromagnetic starting loads with medium starting currents. An MCB with class D trip characteristics trips when the current flowing through it reaches above 10 to 20 times the rated current. Class D MCBs are suitable for inductive and motor loads with high starting currents. Class K MCBs trip when the current flowing through it reaches between 8 to 12 times the rated current. They are suitable for inductive loads and motor loads with high inrush currents. Class Z MCBs are used with highly sensitive devices such as semiconductor devices, and almost never found at construction sites. Hence, it is appreciated that acceptance criteria for current consumption over different time periods is advantageously configured differently. A short burst of high current (e.g., at five times the rated current I_{N}) drawn by the machine will most likely not trip a class C MCB as long as the burst is limited to a time duration below one second or so. The same fuse will be tripped if a current at two times the rated current I_{N} is drawn for two minutes or so.

Hence, it is understood that the acceptance criteria for each averaging function can be configured in dependence of a class of an MCB installation at a work site. This MCB data can, for instance, be downloaded from the server 180, or be configured manually by an operator using the remote control 200.

With reference also to FIG. 6, there is disclosed herein a control unit 110, 210, 600 for controlling power consumption by construction equipment 100 powered at least partly via an electrical mains cable connection 160. The control unit 110, 210, 600 is arranged to obtain data indicative of a current drawn by the construction equipment 100 as function of time, either continuously, periodically, or in response to some event or trigger signal. The control unit may for instance comprise or be connectable to a current sensor arranged to measure a current drawn via the electrical mains cable connection 160, in which case the data indicative of the current drawn by the construction equipment 100 is obtained at least in part from the current sensor. In this way the actual current consumption can be closely monitored, which is an advantage since more accurate current data is obtained. However, the control unit 110, 210, 600 can also be arranged to estimate and/or predict the current drawn by the construction equipment 100 based on a generated hydraulic pressure and flow in a hydraulic system 120 of the construction equipment 100, perhaps measured by a pressure sensor in the hydraulic system 120 or indirectly determined based on hydraulic valve state. It is also possible to estimate and/or predict current consumption based on control commands given to an electric machine or electric actuator of the construction equipment 100. The data indicative of the current drawn by the construction equipment 100 then comprises the estimated and/or predicted current consumption. It is noted that pressure in a hydraulic system is measurable in a cost-efficient manner, while flow is more difficult/costly to measure. Hence, realizations of the techniques discussed herein for hydraulic system which comprises data obtained from pressure sensors will most likely be more common than realizations comprising actual measurement of hydraulic flow.

The control unit 110, 210, 600 is also arranged to process the obtained data using at least a first and a second averaging function, where the first averaging function is associated with a shorter averaging time window Tw1 compared to the second function Tw2. The term “averaging function” is to be construed broadly herein, to encompass any two operations of different time constants or filtering bandwidths, as discussed in more detail below. An averaging filter is an example of an averaging function, since a filter is a type of function taking an input and generating an output. A shorter averaging time window function or filter can also be said to have a larger filtering bandwidth, or to let faster changes in a filter signal through with less attenuation compared to a smaller filtering bandwidth filter.

The outputs of the at least two functions are associated with respective function acceptance criteria, i.e., some form of test which determines if the output of the function is acceptable, or if some action to reduce current consumption is required. The shorter averaging time window function is associated with a more relaxed acceptance criteria compared to the longer averaging time window function, i.e., higher power consumption and drawn current is allowed as long as this higher power consumption is of limited time duration. A threshold value can be used as acceptance criteria, as discussed above, in which case the output of each function is continuously or at least periodically checked against the respective threshold, in order to determine if the output satisfies the acceptance criteria of the function or not. The thresholds can advantageously be determined in dependence of construction site fuse setting, i.e., as a factor multiplied with the fuse rated current, as exemplified above. The control unit 110, 210, 600 is also arranged to trigger a power consumption related action by the construction equipment in case any of the function outputs does not meet the respective function acceptance criterion, such as automatically limiting the current drawn by the demolition robot 100 and/or automatically triggering generation of a notification to a user.

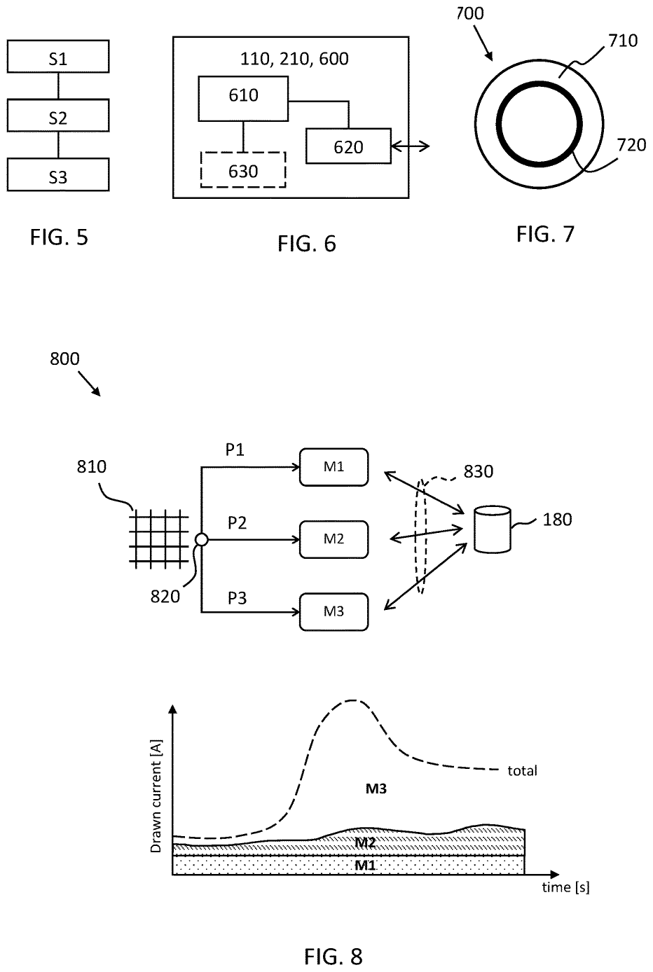

FIG. 5 is a flow chart illustrating a method which also summarizes the concept. The flow chart illustrates a computer-implemented method performed by a construction equipment control unit 110, 180, 210, 600, for controlling power consumption by the construction equipment 100. The method comprises obtaining S1 data indicative of a current drawn by the construction equipment 100 as function of time, processing S2 the obtained data using at least a first and a second averaging function, where the first averaging function is associated with a shorter averaging time window Tw1 compared to the second function Tw2, and where the outputs of the at least two functions are associated with respective function acceptance criteria. The method also comprises triggering S3 a power consumption related action by the construction equipment 100, such as a limitation of the current drawn by the construction equipment or the triggering of a notification in case any of the function outputs does not meet the respective function acceptance criterion.

An averaging function is to be interpreted broadly herein to comprise any function or filter predominantly having a low-pass filter characteristic which suppresses fast variation (where fast is defined relative to the averaging time window). An averaging operation determined for a given time window is the output of an averaging function, and so is the output of a moving average filter. A function or filter having a forgetting factor w<<1, i.e., a filter which outputs a result Īₖ₊₁ according to

$${\overline{I}}_{k + 1} = ( 1 - w ) {\overline{I}}_{k} + w ( {i}_{k} - {\overline{I}}_{k} )$$

where k is a time index, and iₖ is a current drawn by the machine at time index k, is also a form of averaging function, with an averaging time window determined by the magnitude of w.

At least one of the first and the second averaging function can also be realized by an ML algorithm, or an algorithm based on artificial intelligence, such as a random forest method or a neural network, configured to determine if a respective acceptance criterion is fulfilled based on training data comprising power consumption patterns and power outages for different construction site fuse settings. In this case a data set of current consumption for machines which tripped a given fuse and a data set of current consumption which did not trip the given fuse is used to train the ML structure into outputting a result which indicates if the current operation of the machine meets the acceptance criteria of the first and second functions, or if one or more acceptance criterions have been breached. The ML structure is advantageously trained for different MCB classes, such that the ML structure can be configured in dependence of a work site MCB class. To train an ML structure in this manner, real world data on time-stamped current consumption can be collected for different demolition robots 100, along with time instants where a fuse was tripped. The data can be collected for different MCB classes, and the ML structure can then be configured to output information related to if the acceptance criteria are fulfilled or not. The control unit 210 can then use the output of the ML structure to adjust the power consumption of the machine 100 to suit a given fuse installation.

According to some aspects, the control unit 110, 210, 600 is arranged to limit the current drawn by a demolition robot by adjusting one or more hydraulic valve control curves, for example according to the teachings in EP2589709 A2. Alternatively, or as a complement, the control unit 110, 210, 600 can be arranged to limit the current drawn by the demolition robot 100 by adjusting an operation parameter of a hydraulic pump comprised in a hydraulic system 120 of the demolition robot 100, essentially limiting the system pressure and/or flow in the system to consume less power.

The power consumption of a hydraulic system such as the system 120 can, generally, be reduced either by a reduction in system pressure or a reduction in system flow, or a combination of both. The system pressure can be reduced, e.g., by an electronically controlled pressure limiter arranged on a load-sensing (LS) line to the hydraulic pump. This pressure limiter can be controlled from the control unit 210 by transmission of a control signal, such as a message on a controller area network (CAN) bus and allows for setting a ceiling for how high the system pressure can be. If the hydraulic system comprises a fixed displacement pump with a speed-controlled motor, the control unit 210 can also limit the current/torque on the motor to achieve a reduction in consumed power by the machine 100.

The flow in a hydraulic system 220 can be limited by reducing the maximum current sent to the hydraulic system valves, i.e., an adjustment of the control curves of the valves. The control unit can also configure a maximum value for the total flow in the hydraulic system. The total flow limitation can, for instance be set at 70 liters/minute (LPM), in a system where two or more cylinders draw 40 LPM each at full speed. In this case a single cylinder can run at full speed, while two cylinders running actuated concurrently will not be able to reach full speed. Yet another way to perform a limitation on the current drawn by the machine 100 is to adjust the maximum value of the flow according to the pressure that prevails in the machine. If the machine is operating at low pressure, it may be possible to run two or more cylinders at full speed (40 LPM), but if the pressure rises, the control unit can lower the maximum currents to the control valves, i.e., lower the maximum flow through the valves, so that the output/current does not exceed a given limit. Construction equipment can, generally, reduce power consumption by reducing motor speeds, reducing motor torques, or inactivating one or more functions on the machine. Some types of construction equipment, such as demolition robots, may also reduce power consumption by altering behavior, i.e., not using the most power-hungry features on the machine. Thus, a reduction in power consumption can be obtained by inactivating subset of functional features on a machine, at least temporarily. Some construction equipment comprises autonomous control functionality, enabling the equipment to operate in an unsupervised manner. In this case a desired reduction in power can be obtained by re-configuring the behavior of the autonomous control algorithm into a more power efficient mode of operation, where high-power maneuvering is avoided.

The control unit may also be arranged to limit the current drawn by the construction equipment by adjusting an operation of an electric machine and/or electric actuator of the construction equipment. Some construction equipment, including certain types of demolition robots, may be purely electric machines powered by one or more electric machines and/or electric actuators, i.e., lacking hydraulic actuators. The techniques disclosed herein are applicable also to such equipment.

The control unit 110, 210, 600 is preferably arranged to gradually limit the current drawn according to a pre-determined function in case any of the function outputs does not meet the respective function acceptance criterion, as well as to gradually remove an imposed limitation on the current drawn according to a pre-determined function in case all of the function outputs meet the respective function acceptance criterion.

If a power outage should be experienced despite the current limiting operations performed by the control unit, i.e., if a fuse is tripped despite the actions of the control unit 210 discussed herein, it may be advantageous to reconfigure the acceptance criteria in order to be better suited for a given work site and/or work task. Towards this end, the control unit 110, 210, 600 can be arranged to store a recently drawn current in the event of an electrical mains power outage in a storage medium 630 of the control unit. A user can then access the memory and see at which current the fuse was tripped. This information may allow the user or some form of automatic control system, to reconfigure the acceptance criteria to be more suited to a given work site.

The control unit 110, 210, 600 may also be arranged to store recent function outputs in the event of an electrical mains power outage in a storage medium 630 of the control unit, and optionally also to re-configure one or more of the acceptance criteria based on the stored recent function outputs in response to an electrical mains power outage. This information may advantageously be displayed in the remote control, e.g., by the display 230.

Indeed, the current fusing at a work site may not be known a-priori, and this feature allows fuse information of a work site to be discerned in an efficient manner. A power outage event may also be communicated to the server 180, along with the averaging function data and/or a time record of instantaneous current drawn by the machine 100. This data can then be used for analysis at the remote server 180, and also for fine-tuning the ML structure discussed above.

The methods and control units discussed above can also be used collectively for a group of machines 800, as illustrated in FIG. 8, where construction equipment M1, M2 and M3, possibly of different type, is connected to the same electrical mains 810 and share one or more fuses 820. The machines draw powers P1, P2, and P3 from the electrical mains 810. Thus, if the aggregated or total current consumption of the group of machines is too high, the fuse 820 will be tripped. However, one or more of the machines may consume an instantaneous power above the fuse rating, as long as the consumption is temporary and does not extend for a too long time period. The control unit 110, 180, 210, 600 may in this case be arranged to obtain the data indicative of the current drawn by the construction equipment 100 as an aggregated current drawn jointly by two or more pieces of equipment. According to one example the control unit is a centralized control unit, perhaps implemented in the remote server 180 as illustrated in FIG. 8, or in one of the machines M1, M2, M3. This central control unit 180 can be arranged to obtain data indicative of current consumption via wireless link 830 from the two or more pieces of equipment M1, M2, M3. In other words, each machine then periodically reports its power consumption to the central control unit, which keeps a tally of the overall power consumption for each electrical power resource. The control unit, having obtained the data, can then sum up the currents and perform the processing operations discussed above to determine if the current consumption of the group of machines satisfies the acceptance criteria or not. The reporting by each machine M1, M2, M3 can also be configured as a request for increase in power consumption. The control unit, having received a request, may then verify if the request is admissible given the present state of power consumptions of the group of machines. If the request is admissible then a grant can be issued, allowing the machine sending the request to increase its power consumption. If the request is found inadmissible, i.e., if the request would lead to a breach of one or more acceptance criteria, then the control unit will deny the request. The control unit, having received a non-admissible request from one machine may also order a decrease in power consumption by one or more other machines in order to be able to grant the request.

The control unit can also be arranged as a distributed control unit 180 arranged to obtain data indicative of current consumption via wireless links inbetween the two or more pieces of equipment. A distributed control unit executes on more than one physical control unit. Methods for distributing control in this manner are known and will therefore not be discussed in more detail herein. One or more on-board control units and/or one or more remote control units can collaborate in order to determine if the joint power consumption of the group of machines satisfies the acceptance criteria or not. The control unit 110, 180, 210, 600 (either the centralized or the distributed version) may be arranged to limit the current drawn by the two or more pieces of equipment according to a pre-determined priority order. This means that there is an established order of priority in which the machines back off their power consumptions. Some machines may be more important than others. For instance, an air cleaner may be considered a safety device and will not be asked to reduce its power consumption if there is a demolition robot in the group which consumes too much power, and jeopardizes the operation of the air cleaner.

The control unit 110, 180, 210, 600 can also be arranged to limit the current drawn by the two or more pieces of equipment according to a pre-determined decrease distribution. This decrease distribution may, e.g., be a uniform distribution where all machines in the group are asked to back off their power consumption, or a proportional decrease distribution where the control unit requests the machines to decrease power consumption by a percentage, such that high power consumer decrease more than low power consumers.

Some types of construction equipment are associated with a minimum power requirement. These machines cannot be operated unless a certain minimum amount of power can be provided. A control unit arranged in this type of machine may be arranged to inactivate the machine in case the available power becomes too low. Other machines may not allow adjustment of power consumption. This can, for instance, be the case in some types of safety equipment, such as air cleaners, which need to be operated at full power continuously. These aspects can be considered when adjusting power consumption in a group of machines.

FIG. 6 schematically illustrates, in terms of a number of functional units, the general components of the control unit 600, such as the control units 110, 210 discussed above. Processing circuitry 610 is provided using any combination of one or more of a suitable central processing unit CPU, multiprocessor, microcontroller, digital signal processor DSP, etc., capable of executing software instructions stored in a computer program product, e.g., in the form of a storage medium 630. The processing circuitry 610 may further be provided as at least one application specific integrated circuit ASIC, or field programmable gate array FPGA.

Particularly, the processing circuitry 610 is configured to cause the demolition robot 100 to perform a set of operations, or steps, such as the methods discussed in connection to FIG. 5 and the discussions above. For example, the storage medium 630 may store the set of operations, and the processing circuitry 610 may be configured to retrieve the set of operations from the storage medium 630 to cause the device to perform the set of operations. The set of operations may be provided as a set of executable instructions. Thus, the processing circuitry 610 is thereby arranged to execute methods as herein disclosed.

The storage medium 630 may also comprise persistent storage, which, for example, can be any single one or combination of magnetic memory, optical memory, solid state memory or even remotely mounted memory.

The control unit 600 may further comprise an interface 620 for communications with at least one external device. As such the interface 620 may comprise one or more transmitters and receivers, comprising analogue and digital components and a suitable number of ports for wireline or wireless communication.

The processing circuitry 610 controls the general operation of the control unit 600, e.g., by sending data and control signals to the interface 620 and the storage medium 630, by receiving data and reports from the interface 620, and by retrieving data and instructions from the storage medium 630.

FIG. 7 illustrates a computer readable medium 710 carrying a computer program comprising program code means 720 for performing the methods illustrated in FIG. 5, when said program product is run on a computer. The computer readable medium and the code means may together form a computer program product 700.

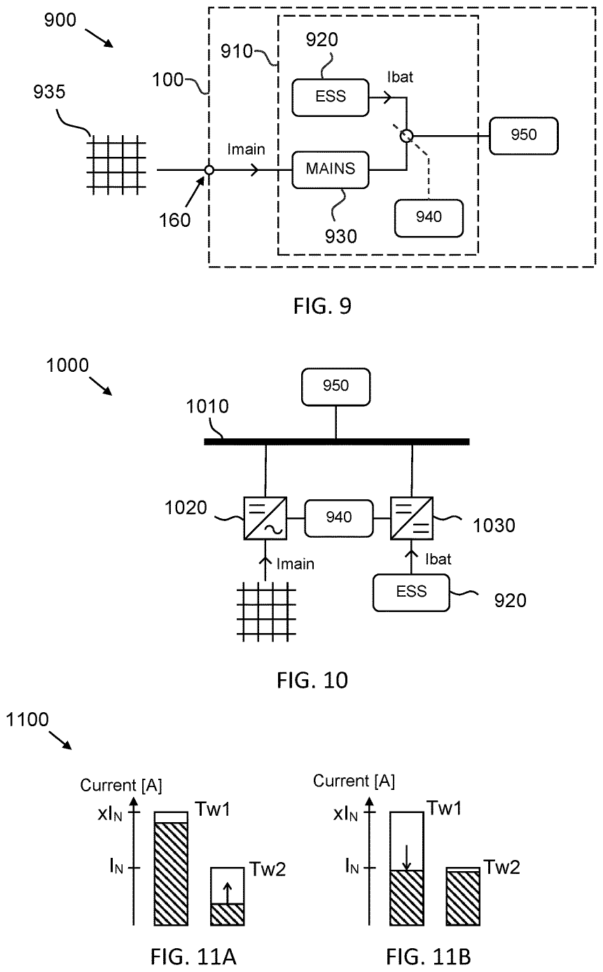

FIG. 9 shows an example use case 900 of the techniques disclosed herein. The Figure schematically illustrates construction equipment 100 that is powered in part by an electrical mains cable connection 930 (such as the cable 160 in FIG. 1) and in part by an ESS arrangement, such as a battery pack, a super-capacitor arrangement, or the like. Li-Ion battery packs are for instance commonly used with this type of hybrid power system. The construction equipment can be of any type, such as a demolition robot, a wall saw, a floor grinder, core drilling equipment, a cut-off tool, a power troweling machine, a blaster, a dust extractor, or a scraper, to name a few examples. Hybrid power systems of this type are previously known from, e.g., EP2842213 B1.

An advantage of this type of hybrid power system is that the peak current or peak power drawn over the electrical mains cable connection 930 can be reduced by transferring extra power from the ESS when needed. Thus, as the current Imain drawn from electrical mains 935 exceeds a threshold current, load is transferred from electrical mains 935 to the ESS 920 by increasing the current Ibat drawn from the ESS. This reduces the load on the electrical mains fuse, and thus prevents tripping of the fuse.

It has been realized that the techniques disclosed herein can be used for controlling the transfer of electrical energy to and/or from the ESS in an improved manner. Based on the discussion above, it is realized that the electrical mains connection can be loaded with a current above a nominal rated long-term use current I_{N} as long as the load is of a limited time duration, as discussed above in connection to FIG. 4. Thus, a demolition robot can use a high power breaker or other actuator for short periods of time, e.g., below 10 seconds or so, without discharging the ESS. The ESS is only used to provide extra power if the load on the electrical mains connection is maintained for longer periods of time, where there is a risk of tripping the fuse. This method of controlling the ESS in a hybrid electrical power system of course preserves state of charge (SOC) in the ESS which is an advantage, and it also reduces wear on the ESS since the ESS is used less frequently.

The same techniques can also be applied when charging the ESS from the electrical mains cable connection. It has been realized that a charging current provided to the ESS from the electrical mains cable connection can be set at a level that results in a current drawn from the electrical mains cable connection above a nominal long-term maximum level, as long as the charging operation is temporary, i.e., as long as the high charging current is not of too long time duration. Thus, a battery comprised in the hybrid electrical power system, such as a Li-Ion battery, may be charged at high current initially, and then the charging current can be gradually reduced in order to not risk tripping a fuse at the construction site. In other words, the charging current provided to the ESS may advantageously be configured such that the current drawn via the electrical mains cable connection is matched to the characteristics of the fuse at the location of the construction equipment. Fuse characteristics were discussed above in connection to FIG. 4, where it is understood that the charging current can be very high initially without risking tripping the fuse, such as three times the nominal rating for about five seconds, and the reduced to about twice the nominal rating for about 30 seconds and then gradually reduced down to nominal level I_{N}.

To summarize, FIG. 9 illustrates a hybrid electrical power system 910 for powering at least one actuator 950 on construction equipment 100, such as a hydraulic pump, an electrical motor, an electro-magnet, or the like. The system 910 comprises an ESS 920 such as a Li-Ion battery bank, an electrical mains cable connection 930, and a control unit 940. The control unit 940 is arranged to obtain data indicative of a current Imain drawn over the electrical mains cable connection 930 as function of time, as discussed above. In other words, the control unit keeps a tally on how much current that has been drawn over the electrical main cable connection over a recent time period, and therefore knows how much current that has passed via the fuse at the site of the electrical mains 935. The control unit 940 is arranged to process the obtained data using at least a first and a second averaging function, as discussed above, where the first averaging function is associated with a shorter averaging time window Tw1 compared to the second averaging function Tw2, and where the outputs of the at least two functions are associated with respective function acceptance criteria, such as thresholds of machine learning structures. Thus, as discussed above, the control unit monitors both short term and long term power consumption. The short term power consumption has its respective limits as discussed above, as does the long term power consumption, where the long term limit is smaller than the short term limit. The control unit may allow high peak currents to be drawn from the electrical mains, as long as the time duration is limited. If the high peak current is drawn for too long, then the second averaging function output will rise. This way the control unit 940 can be arranged to control the transfer of electrical energy to and/or from the ESS 920 based on both filter outputs in relation to the respective filter acceptance criteria. Thus, as discussed above, the ESS is only activated to reduce the current drawn from electrical mains if there is a risk of tripping a fuse at the site of the electrical mains 935, and not otherwise. Also, a charging current provided to the ESS can initially be configured at a current above a nominal rated current, and then gradually decreased in order to not breach the different averaging function acceptance criteria which have been configured according to the teachings herein.

The control unit 940 can for instance be arranged to increase the current Ibat drawn from the ESS 920 in case any of the averaging function outputs does not meet the respective function acceptance criteria. Increasing this current will reduce the load on the electrical mains connection, thus avoiding that the fuse is tripped. The control unit 940 can also be arranged to decrease a current Ibat drawn from the ESS 920 in case both of the averaging function outputs meet the respective function acceptance criteria. This way the ESS is not used unnecessarily. In fact, many types of construction equipment will be able to operate at sites with nominal fuse ratings below the equipment current rating using the techniques disclosed herein, without using the ESS very often or even at all, since the high power consumption events are of short time duration. The often short actuations of a breaker on a demolition robot is one example of when power consumption may be high but is often of short time duration. For instance, suppose that an operation by a demolition robot involving actuation of a breaker results in a drawn current close to 32 A, and that the nominal current rating I_{N} of a fuse at a given construction site is only 16 A. According to the example in FIG. 4, the breaker can then be used for about 30 seconds with relatively small risk of tripping the fuse. Thus, the ESS only needed to be connected to provide extra power in case the breaker is used for a longer time duration.

The control unit 940 may also, as discussed above, be arranged to decrease a charging current provided to the ESS 920 from the electrical mains cable connection 930 in case any of the averaging function outputs does not meet the respective function acceptance criteria, and also to increase a charging current provided to the ESS 920 from the electrical mains cable connection 930 in case both the filter outputs meet the respective filter acceptance criteria. This way the charging of the ESS can be matched to the characteristics of the fuse at a given construction site, which is an advantage. In practice, this often results in a significantly reduced charging time of the ESS, since much higher charging current can be used, especially at the beginning of a charging cycle when the ESS SOC is also low, and the ESS is able to absorb high charging currents. In other words, the control unit 940 may be arranged to control a charging current provided to the ESS 920 from the electrical mains cable connection 930 based on both averaging function outputs in relation to the respective filter acceptance criteria and on a state of charge, SoC, of the ESS 920.

FIG. 10 illustrates an example 1000 of a hybrid electrical power system, similar to that discussed in EP2842213 B1. A direct current (DC) bus 1010 is here used to connect an AC/DC stage 1020 and a DC/DC stage to one or more actuators 950 of the construction equipment. The control unit 940 controls the currents drawn from the electrical mains cable connection and from the ESS according to the teachings herein. The control unit 940 may also control the charging current provided to the ESS 920 from the electrical main cable connection according to the teachings herein.

FIGS. 11A-B show an example use case 1100. The outputs of the first and the second averaging functions are shown as striped bars, and the respective function acceptance criteria are indicated by the white solid bars. According to the illustration, an averaging function output meets the acceptance criterion as long as the striped bar does not go beyond the white bar.

In FIG. 11A the hybrid power system draws a relatively high current over the electrical mains cable connection, which causes the output of the first averaging function to rise to a level above the nominal current I_{N} of the fuse at the construction site. This is allowed, and the ESS is not discharged to reduce the current drawn from electrical mains, since the output of the second averaging function still meets its acceptance criterion. The output of the second averaging function however starts to rise, as indicated by the arrow in FIG. 11A. After some time, the output of the second averaging function has risen enough to come close to the acceptance criterion, and the ESS is therefore discharged. The discharge of the ESS reduces the current drawn over the electrical mains cable connection, such that the output of the first averaging function goes back down, as illustrated in FIG. 11B.

1. A control unit for controlling power consumption by construction equipment powered at least partly via an electrical mains cable connection,
where the control unit is arranged to obtain data indicative of a current drawn by the construction equipment as function of time,
where the control unit is arranged to process the obtained data using at least a first and a second averaging function, where the first averaging function is associated with a shorter averaging time window compared to the second averaging function, and where the outputs of the at least two functions are associated with respective function acceptance criteria,
where the control unit is arranged to trigger an automated power consumption related action by the construction equipment in case any of the function outputs does not meet the respective function acceptance criterion.

2. The control unit according to claim 1, where the triggered power consumption related action comprises limiting the current drawn by the construction equipment, or triggering a notification to a user of the construction equipment.

3. (canceled)

4. The control unit according to claim 1, comprising a current sensor arranged to measure a current drawn via the electrical mains cable connection, where the data indicative of the current drawn by the construction equipment is obtained at least in part from the current sensor.

5. The control unit according to claim 1, arranged to estimate the current drawn by the construction equipment based on a generated hydraulic pressure and flow in a hydraulic system of the construction equipment and/or based on an operation by an electric machine or electric actuator, where the data indicative of the current drawn by the construction equipment comprises the estimated current.

6. The control unit according to claim 1, where at least one of the first and the second averaging function is a moving average filter and where the acceptance criterion comprises a threshold value.

7. The control unit according to claim 1, where at least one of the first and the second averaging function has a low-pass filter characteristic, and where the acceptance criterion comprises a threshold value.

8. The control unit according to claim 6, where the threshold value is determined in dependence of a construction site fuse setting.

9. (canceled)

10. The control unit according to claim 1, arranged to limit the current drawn by the construction equipment by adjusting one or more hydraulic valve control curves of the construction equipment.

11. The control unit according to claim 1, arranged to limit the current drawn by the construction equipment by adjusting an operation parameter of a hydraulic pump comprised in a hydraulic system of the construction equipment such as to reduce a hydraulic system pressure of the construction equipment.

12. The control unit according to claim 1, arranged to limit the current drawn by the construction equipment by adjusting an operation of an electric machine and/or electric actuator of the construction equipment.

13-22. (canceled)

23. The control unit according to claim 1, for controlling power consumption by construction equipment powered at least partly by an electrical energy storage, ESS,
where the data obtained by the control unit is indicative of a current drawn by the construction equipment over the electrical mains cable connection as function of time, and
where the automated power consumption related action comprises control of electrical energy transferred to and/or from the ESS based on both averaging function outputs in relation to the respective filter acceptance criteria.

24-29. (canceled)

30. Concrete processing equipment comprising a control unit according to claim 1.

31. The concrete processing equipment according to claim 30, comprising any of a demolition robot, a wall saw, a floor grinder, core drilling equipment, a cut-off tool, a power troweling machine, a blaster, a dust extractor, or a scraper.

32. A computer-implemented method performed by a construction equipment control unit, for controlling power consumption by the construction equipment, the method comprising
obtaining data indicative of a current drawn by the construction equipment as function of time,
processing the obtained data using at least a first and a second averaging function, where the first averaging function is associated with a shorter averaging time window compared to the second function, where the outputs of the at least two functions are associated with respective function acceptance criteria, and
triggering a power consumption related action by the construction equipment in case any of the function outputs does not meet the respective function acceptance criterion.

33. A hybrid electrical power system for powering at least one actuator on construction equipment, the system comprising an electrical energy storage, ESS, an electrical mains cable connection, and a control unit,
where the control unit is arranged to obtain data indicative of a current drawn over the electrical mains cable connection as function of time,
where the control unit is arranged to process the obtained data using at least a first and a second averaging function, where the first averaging function is associated with a shorter averaging time window compared to the second averaging function, and where the outputs of the at least two functions are associated with respective function acceptance criteria,
where the control unit is arranged to control a transfer of electrical energy to and/or from the ESS based on both filter outputs in relation to the respective filter acceptance criteria.

34. The hybrid electrical power system according to claim 33, where the control unit is arranged to increase a current drawn from the ESS in case any of the averaging function outputs does not meet the respective function acceptance criteria.

35. The hybrid electrical power system according to claim 33, where the control unit is arranged to decrease a current drawn from the ESS in case both of the averaging function outputs meet the respective function acceptance criteria.

36. The hybrid electrical power system according to claim 33, where the control unit is arranged to decrease a charging current provided to the ESS from the electrical mains cable connection in case any of the averaging function outputs does not meet the respective function acceptance criteria.

37. The hybrid electrical power system according to claim 33, where the control unit is arranged to increase a charging current provided to the ESS from the electrical mains cable connection in case both the filter outputs meet the respective filter acceptance criteria.

38. The hybrid electrical power system according to claim 33, where the control unit is arranged to control a charging current provided to the ESS from the electrical mains cable connection based on both averaging function outputs in relation to the respective filter acceptance criteria and on a state of charge, SoC, of the ESS.
